(19) United States
(12) Patent Application Publication
(10) Pub. No.: US 2002/0033191 A1
(43) Pub. Date: Mar. 21, 2002

(54) Silicon-type thin-film formation process, silicon-type thin film, and photovoltaic device

(76) Inventors: Takaharu Kondo, Kyoto (JP); Koichi Matsuda, Kyoto (JP)

Correspondence Address: FITZPATRICK CELLA HARPER & SCINTO, 30 ROCKEFELLER PLAZA, NEW YORK, NY, 10112, US

(21) Appl. No.: 09/866,665

(22) Filed: May 30, 2001

(30) Foreign Application Priority Data
May 31, 2000 (JP) 162804/2000

(51) Int. Cl. H01L 31/00

(52) U.S. Cl. 136/249; 136/261; 427/588; 423/348

(57) ABSTRACT

In a process for forming a silicon-type thin film by high-frequency plasma chemical vapor deposition, silicon fluoride and hydrogen are contained in a material gas and oxygen atoms are incorporated in the material gas in a concentration of from 0.1 ppm to 0.5 ppm based on that of silicon atoms. By this process, photovoltaic devices having a good photoelectric conversion efficiency and superior adherence and environmental resistance can be formed at a cost made greatly lower than ever.

### BACKGROUND OF THE INVENTION

1. Field of the Invention

This invention relates to a silicon-type thin-film formation process, a silicon-type thin film, and a photovoltaic device such as a solar cell or a sensor, formed by depositing a semiconductor layer having at least one set of p-i-n junction.

2. Related Background Art

As a process for forming silicon thin films showing crystallizability, a process such as film casting in which a film is grown from a liquid phase is conventionally used, which, however, requires high-temperature treatment and has had problems on achieving mass productivity and cost saving.

As a process other than the film casting, for forming silicon thin films showing crystallizability, Japanese Patent Application Laid-Open No. 5-136062 discloses a process in which hydrogen plasma treatment is made after the formation of amorphous silicon and this is repeated to form a polycrystalline silicon film.

In general, in photovoltaic devices making use of silicon thin films showing crystallizability, it is known that an influence of dangling bonds of silicon at crystal grain boundaries, any strain or distortion produced at crystal grain boundaries and an imperfection of crystals themselves may obstruct carrier mobility to adversely affect photoelectric characteristics required as photovoltaic devices.

As a countermeasure for making them less affect the characteristics, in order to improve crystallinity and crystallizability it has been necessary to design, e.g., to lower film deposition rate or to form films while repeating the formation of silicon films and their annealing in an atmosphere of hydrogen. Such treatment is the cause of long film-deposition time and high cost.

### SUMMARY OF THE INVENTION

Accordingly, an object of the present invention is to solve the above problem to provide a process by which silicon thin films having superior photoelectric characteristics can be formed at a film deposition rate kept at an industrially practical level, and also provide a silicon thin film and a photovoltaic device.

The present invention provides a process for forming a silicon-type thin film by high-frequency plasma CVD (chemical vapor deposition), wherein silicon fluoride and hydrogen are contained in a material gas and oxygen atoms are incorporated in the material gas in a concentration of from 0.1 ppm to 0.5 ppm based on that of silicon atoms.

The present invention also provides a silicon-type thin film formed by high-frequency plasma CVD, the silicon-type thin film having been formed under conditions that silicon fluoride and hydrogen are contained in a material gas and oxygen atoms are incorporated in the material gas in a concentration of from 0.1 ppm to 0.5 ppm based on that of silicon atoms.

The silicon-type thin film may preferably contain from 1.5×10¹⁸ atoms/cm³ to 5.0×10¹⁹ atoms/cm³ of oxygen atoms.

The present invention still also provides a photovoltaic device comprising a substrate and formed thereon a semiconductor layer having at least one set of p-i-n junction, wherein at least one i-type semiconductor layer has been formed by a process for forming a silicon-type thin film by high-frequency plasma CVD, the i-type semiconductor layer having been formed under conditions that silicon fluoride and hydrogen are contained in a material gas and oxygen atoms are incorporated in the material gas in a concentration of from 0.1 ppm to 0.5 ppm based on that of silicon atoms.

The present invention further provides a silicon-type thin film comprising from 1.5×10¹⁸ atoms/cm³ to 5.0×10¹⁹ atoms/cm³ of oxygen atoms.

The present invention still further provides a photovoltaic device comprising a substrate and formed thereon a semiconductor layer having at least one set of p-i-n junction, wherein at least one i-type semiconductor layer contains from 1.5×10¹⁸ atoms/cm³ to 5.0×10¹⁹ atoms/cm³ of oxygen atoms.

The hydrogen in the material gas may preferably be fed at a flow rate not lower than the flow rate of the silicon fluoride. The silicon-type thin film and the i-type semiconductor layer may preferably be formed at a pressure of 50 mTorr or higher. The silicon-type thin film and the i-type semiconductor layer may also preferably have a Raman scattering intensity due to crystalline component which intensity is at least three times the Raman scattering intensity due to amorphous component. The silicon-type thin film and the i-type semiconductor layer may still also preferably have a diffraction intensity of the (220)-plane as measured by X-ray or electron-ray diffraction, which is in a proportion of 50% or more with respect to the total diffraction intensity.

### BRIEF DESCRIPTION OF THE DRAWINGS

FIG. 1 is a diagrammatic cross-sectional view showing an example of a photovoltaic device according to an embodiment of the present invention.

FIG. 2 is a diagrammatic cross-sectional view showing an example of a deposited-film formation apparatus for producing silicon-type thin films and photovoltaic devices according to an embodiment of the present invention.

FIG. 3 is a diagrammatic cross-sectional view showing an example of a thin film according to an embodiment of the present invention.

FIG. 4 is a diagrammatic cross-sectional view showing an example of a photovoltaic device having a silicon-type thin film according to an embodiment of the present invention.

FIG. 5 is a diagrammatic cross-sectional view showing an example of a photovoltaic device having a silicon-type thin film according to an embodiment of the present invention.

### DESCRIPTION OF THE PREFERRED EMBODIMENTS

As a result of extensive studies repeatedly made in order to solve the problems stated previously, the present inventors have discovered that, in a process for forming a silicon-type thin film by high-frequency plasma CVD, silicon fluoride and hydrogen may be contained in a material gas and oxygen atoms may be incorporated in the material gas in a concentration of from 0.1 ppm to 0.5 ppm based on that of silicon atoms, whereby silicon-type thin films having a high crystallinity and a good crystallizability and oriented in the (220)-direction can be deposited at a high rate. They have also discovered that this silicon-type thin film may be used in at least part of at least one i-type semiconductor layer of a photovoltaic device comprising a substrate and formed thereon a semiconductor layer having at least one set of p-i-n junction, whereby photovoltaic devices having a good photoelectric conversion efficiency and superior adherence and environmental resistance can be formed at a cost made greatly lower than ever.

The above construction provides the following advantages.

The process for forming a crystal-phase-containing silicon-type thin film by plasma CVD making use of high-frequency power may require a shorter processing time than solid-phase reaction and also enables processing temperature to be set lower. Hence, this is advantageous for the achievement of low cost. Especially in the case of photovoltaic devices having p-i-n junction, this effect can greatly be brought about by applying the process in i-type semiconductor layers having a large layer thickness. Stated specifically, a process of forming such layers by CVD making use of a high-frequency power with a frequency of 10 MHz to 10 GHz is particularly preferred.

Where i-type semiconductor layers which function substantially as light-absorption layers are formed as i-type semiconductor layers containing crystalline phases, there is an advantage that the phenomenon of photo-deterioration that is caused by the Staebler-Wronski effect, questioned in the case of amorphous semiconductors, can be kept from occurring. Here, in a high-frequency plasma CVD in which the material gas containing silicon fluoride and hydrogen are used as a material gas, various active species are formed in the plasma. As types of the active species in plasma, they may include SiFₙHₘ (0≦n≦4, 0≦m≦4, 0≦m+n≦4), HF, F and H. How these active species function is unclear in detail. It is presumed to be a characteristic feature that, in addition to active species contributing to the deposition of silicon-type thin films, there are active species contributing to etching. Hence, the deposition of films proceeds while etching Si-Si bonds, which are present at film surface and have a relatively weak bonding force, so that silicon-type thin films having less amorphous regions and having a high crystallinity can be formed, as so considered. It is also considered that, in the course of etching, radicals are formed as the bonds are cut off, so that structural relaxation is accelerated, and this enables formation of good-quality silicon-type thin films at a lower-temperature processing temperature.

Here, as a problem which may arise when a silicon-type thin film containing crystalline phases is used in the i-type semiconductor layer, it is known that crystal grain boundaries affect both large-number carriers and small-number carriers to cause deterioration of performance. In order to keep the crystal grain boundaries from affecting these, it is considered to be one of effective means to enlarge the grain diameter of crystals in the i-type semiconductor layer to lower crystal grain boundary density. What is especially important as a technical subject is that crystalline phases having a low crystal grain boundary density are formed from the initial stage where the i-type semiconductor layer is formed. Now, the present inventors have discovered that adding a minute quantity of oxygen in addition to the silicon fluoride and hydrogen in the material gas used when the i-type semiconductor layer is formed enables crystal nuclei to be kept from being formed at the initial stage of film deposition, and the grain diameter of crystals in the i-type semiconductor layer increases relatively, so that a silicon-type thin film having a small crystal grain boundary density can be formed.

The reason of such a phenomenon is unclear in detail. It is considered that the formation of crystal nuclei requires formation of nuclei larger than the critical radii that depend on even balance between changes of free energy which are caused by being crystallized and changes of free energy which are attributable to the surface area to be given. It is further considered that, after the crystal nuclei have been formed, the crystallization proceeds in the form of growth of crystal nuclei when the growth of crystals around the existing crystal nuclei is more advantageous in respect of energy than the formation of new crystal nuclei that is accompanied with a great increase in surface area energy. Taking this into consideration, oxygen is introduced into silicon networks at the time of deposited-film formation by incorporating a minute quantity of oxygen in silicon fluoride to provide an amorphous structure at that part where it has been introduced, which tends to undergo the action of being etched by the active species composed of silicon fluoride and hydrogen. As a result, most buds of crystal nuclei are kept from growing to the critical radii, resulting in a low crystal nuclei formation density, as so considered. It is also presumed that, in respect of regions where crystal nuclei have grown to a size larger than the crystal critical radii, the oxygen more accelerates the relaxation in the vicinity of surface, so that the effect of deposition becomes relatively more predominant than the etching. Thus, it is presumed that the silicon-type thin film having a small crystal grain boundary density can be formed. However, the presence of any excess oxygen is not preferable because it may cause a disturbance of silicon networks, a lowering of crystallizability and a lowering of conductivity.

Taking the foregoing into consideration, the above effect can more preferably be brought about where, in the process for forming a silicon-type thin film by high-frequency plasma CVD, the silicon fluoride and hydrogen are contained in the material gas and the oxygen atoms are incorporated in the material gas in a concentration of from 0.1 ppm to 0.5 ppm based on that of silicon atoms.

Silicon which shows crystallizability commonly has diamond structure, and silicon atoms hold four coordination positions. In the case of silicon-type thin films containing crystalline phases, it is considered that irregular boundaries having a disordered crystallographic regularity may occur at some part because of strain or distortion of structure and concentration of transition. Atoms which inactivate dangling bonds present at such irregular boundaries may include, when the silicon fluoride and hydrogen are contained in the material gas, hydrogen and fluorine, which are individually effective. It is considered that the incorporation of oxygen, having a larger valence, is more effective in regions having a relatively high density of dangling bonds. Also, the fluorine is an atom having a high electronegativity, and is considered to change a charged condition in the vicinity of fluorine atoms in the silicon networks to form curves of bands. In the case where oxygen atoms are incorporated, it is considered that they can keep the silicon networks from being affected by such a change. Also, the interface formed by crystal grain boundaries is considered to show almost metallic behavior, and may cause a lowering of the resistance of shunts when channels are formed along interfaces and electric currents flow therethrough. Here, it is considered that the introduction of oxygen can keep such channels from being formed.

The above effect can more preferably be brought about where the silicon-type thin film contains oxygen atoms in an amount of from 1.5×10¹⁸ atoms/cm³ to 5.0×10¹⁹ atoms/cm³, still more preferably from 5.0×10¹⁸ atoms/cm³ to 3.0×10¹⁹ atoms/cm³, and most preferably from 8.0×10¹⁸ atoms/cm³ to 2.0×10¹⁹ atoms/cm³.

Another factor for controlling the crystal grain diameter is the orientation preference of crystal grains. Where the deposition of a film proceeds in random crystal directions, it is considered that individual crystal grains collide with each other in the course of growth to come to have a relatively small crystal grain size. However, the crystal grains can be kept from such mutual random collision by orienting crystal grains in a specific direction to make uniform the directionality of growth, so that the crystal grains can be expected to be made to have a larger grain diameter. Also, in the crystalline silicon having diamond structure, the (220)-plane is preferred because it has the highest in-plane atomic density and hence, when this plane is set as growth plane, silicon-type thin films having a good adherence can be formed. From an ASTM card, in the case of non-oriented crystalline silicon, the (220)-plane has a diffraction intensity in a proportion of about 23% with respect to the total diffraction intensity corresponding to eleven reflections from the low-angle side, and it follows that any structure whose proportion of diffraction intensity of the (220)-plane is more than 23% has orientation preference in this plane direction. In particular, structure whose proportion of diffraction intensity of the (220)-plane is 50% or more, the above effect is more promoted, thus such structure is particularly preferred. As a result of extensive studies repeatedly made taking account of keeping the phenomenon of photo-deterioration from being caused by the Staebler-Wronski effect and taking account of any lowering of the crystal grain boundary density, the present inventors have discovered that the Raman scattering intensity (as a typical example, about 520 cm⁻¹) that is due to a crystalline component is at least three times the Raman scattering intensity (as a typical example, about 480 cm⁻¹) that is due to an amorphous component.

In order to materialize the formation of the silicon-type thin film having the above orientation preference and crystallinity, at a high film deposition rate in total while the film is deposited and simultaneously etched, it is an important technical subject to control plasma processing. In order to carry out high-rate film deposition, it is necessary to increase electric power applied in order to enhance the decomposition efficiency of material gases. Here, not only neutral active species which has the function of deposition and etching but also ions increase simultaneously. It is considered that the ions are accelerated by electrostatic attraction force in sheath regions in the vicinity of the substrate, and may be an obstacle to the formation of high-quality silicon-type thin films, e.g., cause distortion of crystal lattice as ion bombardment in deposited films or cause formation of voids in films, and may lower adherence to underlying layers and environmental resistance. Here, where the plasma is made to take place under conditions of a relatively high pressure, it can be expected that the ions in plasma can have more opportunities of their collision with other ions, active species and so forth to lessen ion bombardment or decrease in ion density itself.

In the state where the pressure is set high, the plasma can be made to take place in a high density in the vicinity of the substrate, and this is presumed to more activate deposited-film surface reaction such as the action of deposition and the action of etching. In order to form the high-quality silicon-type thin films at a high rate as stated above, the regulation of forming conditions such as pressure and electric power for plasma and the control of plasma density and types of active species are considered to enable such formation. As a result of extensive studies repeatedly made by the present inventors, the pressure may preferably be set at 50 mTorr or above, taking account of the effect of lessening damage by ions and the effect brought about by the introduction of oxygen to crystal grain boundaries.

Where the high-rate film deposition is carried out at a high pressure in an SiH₄ system, a higher-order silane may occur as a reaction by-product to lower crystallizability or powder such as polysilane may occur to accumulate in the apparatus or evacuation system to cause a decrease in operation efficiency of the apparatus. In the case of the silicon fluoride, however, any polysilane is little seen to occur. This is advantageous also in view of maintenance.

In the case where silicon thin films are formed by high-frequency plasma CVD, the formation of halogenated-silane-type active species containing hydrogen, such as SiF₂H and SiFH₂ formed by adding hydrogen to silicon fluoride, is considered to enable the high-rate film deposition rate. In order to form such halogenated-silane-type active species containing hydrogen, such as SiF₂H and SiFH₂, it is necessary to provide the step of active reaction of SiF₄ with active hydrogen. Taking account of this point, too, the film deposition process of the present invention, in which the pressure is set relatively high, is considered advantageous. It is presumed that the halogenated-silane-type active species containing hydrogen, such as SiF₂H and SiFH₂, contribute greatly to the deposition to enable the high-rate film deposition. As other effect attributable to hydrogen, the crystallizability can be improved because of the activation of surface diffusion that is attributable to hydrogen radicals, the effect of withdrawing F (fluorine) from the film surface and the vicinity of the surface can be obtained, and grain boundaries can be inactivated by the passivation effect. Thus, the role of hydrogen in this reaction system is considered to be great. In particular, in order to bring about the above effect greatly, as the flow rates of silicon fluoride and hydrogen the flow rate of hydrogen may preferably be not lower than the flow rate of the silicon fluoride.

Components of the photovoltaic device of the present invention are described below.

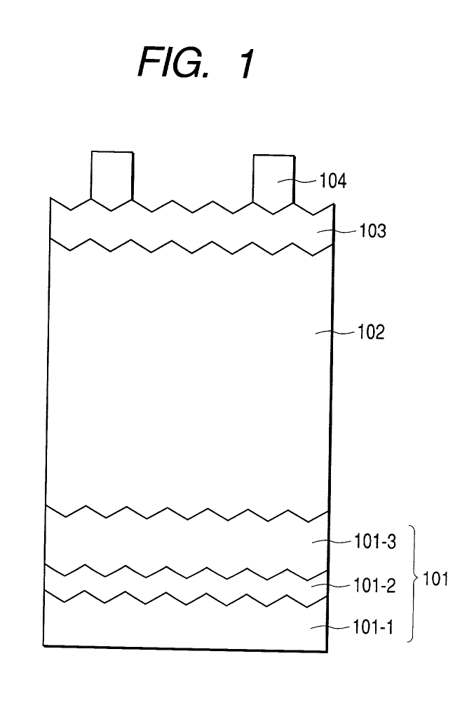

FIG. 1 is a diagrammatic cross-sectional view showing an example of the photovoltaic device of the present invention. In FIG. 1, reference numeral 101 denotes a substrate member; 102 a semiconductor layer; 103, a second transparent conductive layer; and 104, a collector electrode. Also, reference numeral 101-1 denotes a substrate; 101-2, a metal layer; and 101-3, a first transparent conductive layer; these are constituents of the substrate member 101.

(Substrate)

As the substrate 101-1, a platelike member or sheetlike member made of metal, resin, glass, ceramic or semiconductor bulk may preferably be used. Its surface may have a fine unevenness. A transparent substrate may be used so that the device can be so set up that light enters it on the substrate side. Also, the substrate may have the form of a continuous sheet so that continuous film deposition can be carried out by roll-to-roll processing. In particular, materials having a flexibility, such as stainless steel and polyimides, are preferable as materials of the substrate 101-1.

(Metal Layer)

The metal layer 101-2 has function as an electrode and function as a reflecting layer from which the light having reached the substrate 101-1 reflects so as to be reused. As materials therefor, preferably usable are Al, Cu, Ag, Au, CuMg, AlSi and so forth. As processes for its formation, processes such as vacuum evaporation, sputtering, electrodeposition and printing are preferred. The metal layer 101-2 may preferably have an unevenness at its surface. This can elongate the optical path in the semiconductor layer 102 to increase short-circuit current. Where the substrate 101-1 has conductivity, the metal layer 101-2 need not be formed. Also, in the case where the light is made to enter the device on the substrate 101-1 side, it is better not to form the metal layer 101-2.

(First Transparent Conductive Layer)

The first transparent conductive layer 101-3 has the function of increasing irregular reflection of incident light and reflected light to elongate the optical path in the semiconductor layer 102. It also has the function of preventing elements of the metal layer 101-2 from diffusing to the semiconductor layer or causing migration to shunt the photovoltaic device. Also, since it has an appropriate resistance, it has the function of preventing short circuit from being caused by defects such as pinholes in the semiconductor layer. Still also, like the metal layer 101-2, the first transparent conductive layer 101-3 may preferably have an unevenness at its surface. The first transparent conductive layer 101-3 may preferably be formed of a conductive oxide such as ZnO or ITO (indium-tin-oxide), and may preferably be formed by a process such as vacuum evaporation, sputtering, CVD or electrodeposition. A substance capable of changing conductivity may be added to any of these conductive oxides.

The first transparent conductive layer 101-3 may preferably be a zinc oxide film formed by a process such as sputtering or electrodeposition. Conditions for forming the zinc oxide film preferably used as the first transparent conductive layer are described below.

Methods, kinds and flow rates of gases, internal pressure, electric power to be applied, film deposition rate and substrate temperature have a great influence as the conditions for forming the zinc oxide film by sputtering. For example, where the zinc oxide film is formed by DC magnetron sputtering using a zinc oxide target, as the kinds of gases, they may include Ar, Ne, Kr, Xe, Hg and O₂. The flow rates may differ depending on the size of apparatus and evacuation rate. For example, it may preferably be from 1 sccm to 100 sccm when film deposition space has a volume of 20 liters. The internal pressure at the time of film deposition may preferably be from 1×10⁻⁴ Torr to 0.1 Torr. The electric power to be applied, which depends on the size of the target, may preferably be from 10 W to 100 kW when the target has a diameter of 15 cm. Also, the substrate temperature, which depends on the film deposition rate, may preferably be from 70° C. to 450° C. when the film is deposited at a rate of 1 μm/h.

As conditions for forming the zinc oxide film by electrodeposition, an aqueous solution containing nitrate ions and zinc ions may preferably be used in an anti-corrosive container. The nitrate ions and zinc ions may preferably be contained in a concentration in the range of from 0.001 mol/liter to 1.0 mol/liter, and more preferably in the range of from 0.01 mol/liter to 0.5 mol/liter, and still more preferably in the range of from 0.1 mol/liter to 0.25 mol/liter. A feed source or sources of the nitrate ions and zinc ions may be, but not particularly limited to, zinc nitrate as a feed source of both ions, or a mixture of a water-soluble nitrate such as ammonium nitrate as a feed source of the nitrate ions and a zinc salt such as zinc sulfate as a feed source of the zinc ions. It is also preferable to further add a carbohydrate to the above aqueous solution in order to keep any abnormal growth from occurring and to improve adherence. As the carbohydrate, usable are, but not particularly limited to, monosaccharides such as glucose (grape sugar) and fructose (fruit sugar), disaccharides such as maltose (malt sugar) and sucrose (cane sugar), polysaccharides such as dextrin and starch, and a mixture of any of these. The carbohydrate in the aqueous solution may preferably be in an amount in the range of from 0.001 g/liter to 300 g/liter, more preferably in the range of from 0.005 g/liter to 100 g/liter, and still more preferably in the range of from 0.01 g/liter to 60 g/liter, in approximation, which depends on the type of carbohydrate. In the case where the zinc oxide film is deposited by electrodeposition, a substrate on which the zinc oxide film is to be deposited may preferably be set as the cathode and zinc, platinum or carbon as the anode in the aqueous solution. Here, electric current which flows through a load resistor may preferably be in a current density of from 10 mA/dm² to 10 A/dm².

(Substrate Member)

By the process described above, the metal layer 101-2 optionally and the first transparent conductive layer 101-3 are superposed on the substrate 101-1 to form the substrate member 101. In order to make the integration of devices easy, an insulating layer may also be formed as an intermediate layer in the substrate member 101.

(Semiconductor Layer)

As a chief material for the silicon-type thin film and semiconductor layer 102 of the present invention, silicon having an amorphous phase or a crystalline phase or further a mixed-phase system of these is used. In place of the silicon Si, an alloy of Si with C or Ge may be used. In the semiconductor layer 102, hydrogen atoms and/or halogen atoms are simultaneously contained, which may preferably be in a content of from 0.1 atom % to 40 atom %. To form the semiconductor layer as a p-type semiconductor layer, it contains a Group III element of the periodic table, and as an n-type semiconductor layer, a Group V element. As electrical characteristics of the p-type layer and n-type layer, the layers may preferably have an activation energy of 0.2 eV or lower, and most preferably 0.1 eV or lower; and a specific resistance (volume resistivity) of 100 ΩΩcm or below, and most preferably 1 Ω·cm or below. In the case of a stacked cell (a photovoltaic device having p-i-n junction in plurality), the i-type semiconductor layer of p-i-n junction closest to the light incident side may preferably have a broad band gap, and have a narrower band gap as the i-type layer is that of p-i-n junction on the deeper side or the substrate side. Also, in the interior of the i-type layer, it may preferably have a minimum value of the band gap at its part closer to the p-type layer than the middle in its layer thickness direction.

As a doped layer (p-type layer or n-type layer) on the light incident side, suited is a crystalline semiconductor less absorptive of light or a semiconductor having a broad band gap.

As an example of a stacked cell having two sets of p-i-n junction superposed, it may be a cell having, as combination of i-type silicon-type semiconductor layers, from the light incident side, (amorphous semiconductor layer+semiconductor layer containing crystalline phase) or (semiconductor layer containing crystalline phase+semiconductor layer containing crystalline phase). Also, as an example of a stacked cell having three sets of p-i-n junction superposed, it may be a cell having, as combination of i-type silicon-type semiconductor layers, from the light incident side, (amorphous semiconductor layer+amorphous semiconductor layer+semiconductor layer containing crystalline phase), (amorphous semiconductor layer+semiconductor layer containing crystalline phase+semiconductor layer containing crystalline phase) or (semiconductor layer containing crystalline phase+semiconductor layer containing crystalline phase+semiconductor layer containing crystalline phase).

As the i-type semiconductor layer, it may preferably be a layer whose coefficient of absorption (α) of light (wavelength: 630 nm) is 5,000 cm⁻¹ or higher, photoconductivity (σp) under irradiation by artificial sunlight by means of a solar simulator (AM 1.5; 5,100 mW/cm²) is 10×10⁻⁵ S/cm or higher, dark conductivity (ad) is 10×10⁻⁶ S/cm or lower, and Urbach energy measured by the constant photocurrent method (CPM) is 55 meV or lower. Even an i-type semiconductor layer slightly made into the p-type or n-type may be used as the i-type semiconductor layer.

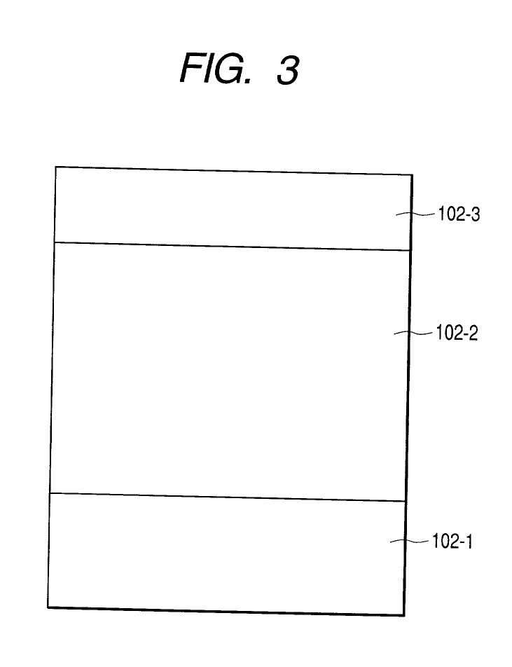

To further add description on the semiconductor layer 102, which is a component of the present invention, FIG. 3 is a diagrammatic cross-sectional view showing an example of a semiconductor layer 102 having a set of p-i-n junction as an example of the photovoltaic device according to the present invention. In FIG. 3, reference numeral 102-1 denotes a semiconductor layer showing a first conductivity type, on which an i-type semiconductor layer 102-2 containing a crystalline phase, comprising the silicon-type thin film of the present invention, and a semiconductor layer 102-3 showing a second conductivity type are further superposed. In the semiconductor layer having p-i-n junction in plurality, at least one of them may preferably be constituted as described above. Also, the conductivity type of the semiconductor layer on the light incident side may be either of p-type and n-type.

(Semiconductor Layer Formation Process)

For the formation of the silicon-type thin film of the present invention and the semiconductor layer 102 described above, high-frequency plasma CVD is suited. A preferred example of the procedure to form the semiconductor layer 102 by the high-frequency plasma CVD is given below.

(1) The inside of a semiconductor-forming vacuum chamber which can be brought into a vacuum is evacuated to a stated deposition pressure.

(2) Material gases such as film-forming material gas and dilute gas are fed into a deposition chamber in the vacuum container, and the inside of the deposition chamber is set to a stated deposition pressure, evacuating its inside by means of a vacuum pump.

(3) The substrate member 101 is set to have a stated temperature by means of a heater.

(4) A high-frequency power generated by a high-frequency power source is guided into the deposition chamber. As a method for guiding it into the deposition chamber, it may include a method in which the high-frequency power is guided by a waveguide and guided into the deposition chamber through a dielectric-material window, and a method in which the high-frequency power is guided by a coaxial cable and guided into the deposition chamber through a metal electrode.

(5) Plasma is caused to take place in the deposition chamber to decompose the material gases to form a deposited film on the substrate member 101 placed in the deposition chamber. This procedure is repeated a plurality of times as necessary, to form the semiconductor layer 102, having p-i-n junction.

The semiconductor layer 102 may be formed under conditions of a deposition chamber internal substrate temperature of from 100° C. to 450° C. and a pressure of from 0.5 mTorr to 10 Torr. When the silicon-type thin film (i-type semiconductor layer) of the present invention is formed, it may be formed at a pressure of 50 mTorr or higher and a high-frequency power density of from 0.001 to 1 W/cm³ (applied electric power/deposition chamber volume) as preferable conditions.

As material gases suited for forming the semiconductor layer 102, they may include material gases which contain any of gasifiable compounds containing silicon atoms, such as SiH₄ and Si₂H₆, and silicon halides such as SiF₄, Si₂F₆, SiH₂F₂, SiH₂Cl₂, SiCl₄ and Si₂Cl₆. Gas materials standing vaporized at normal temperature are put in gas cylinders for their use, and those standing liquefied are bubbled with an inert gas when used. In the case of an alloy system, a gasifiable compound containing Ge or C, such as GeH₄ or CH₄, may preferably further be added to the material gases.

The material gases may preferably be fed into the deposition chamber after they have been diluted with a dilute gas. The dilute gas may include H₂ and He.

As material gases for forming the silicon-type thin film of the present invention, they include silicon fluorides such as SiF₄, Si₂F₆ and SiH₂F₂, and any of those to which oxygen has further been added. The oxygen may be added by separately introducing oxygen from an oxygen cylinder. Alternatively, a high amount of oxygen is previously contained in a material gas cylinder and/or a dilute gas cylinder. The oxygen containing cylinder is produced, for example, by introducing a predetermined amount of oxygen during a gas production step.

As a dopant gas for making the semiconductor layer into a p-type layer, B₂H₆, BF₃ or the like may be used. Also, as a dopant gas for making the semiconductor layer into an n-type layer, PH₃, PF₃ or the like may be used. Where crystalline-phase thin films or films less absorptive of light or having a broad band gap such as SiC films are formed, it is preferable to use the dilute gas in a larger proportion for the material gas and to apply a high-frequency power having a relatively high power density.

(Second Transparent Conductive Layer)

The second transparent conductive layer 103 is an electrode on the light incident side and at the same time may be made to have a suitable layer thickness so as to function also as a reflection preventive layer. The second transparent conductive layer 103 is required to have a high transmittance in a wavelength region of the light the semiconductor layer 102 can absorb, and to have a low resistivity. It may preferably have a transmittance at 550 nm of 80% or higher, and more preferably 85% or higher. As for the resistivity, it may preferably be 5×10⁻³ Ω·cm or lower, and more preferably 1×10⁻³ Ω·cm or lower.

As materials for the second transparent conductive layer 103, preferably usable are, e.g., ITO, ZnO and In₂O₃. As processes for its formation, processes such as vacuum evaporation, CVD, spraying, spin coating and dipping are preferred. A substance capable of changing conductivity may be added to any of these materials.

(Collector Electrode)

The collector electrode 104 is provided on the transparent electrode (second transparent conductive layer 103) in order to improve electricity collection efficiency. As methods for its formation, preferred are a method in which an electrode-pattern metal is formed by sputtering using a mask, a method in which a conductive paste or solder paste is printed, and a method in which a metal wire is fastened with a conductive paste.

Incidentally, a protective layer may optionally be formed on each side of the photovoltaic device. At the same time, a reinforcing material such as steel sheet may also be used in combination, on the back (the side opposite to the light incident side) of the photovoltaic device.

### EXAMPLES

In the following Examples, the present invention is described in greater detail, taking the case of a solar cell as the photovoltaic device. These Examples by no means limit the scope of the present invention.

### Example 1

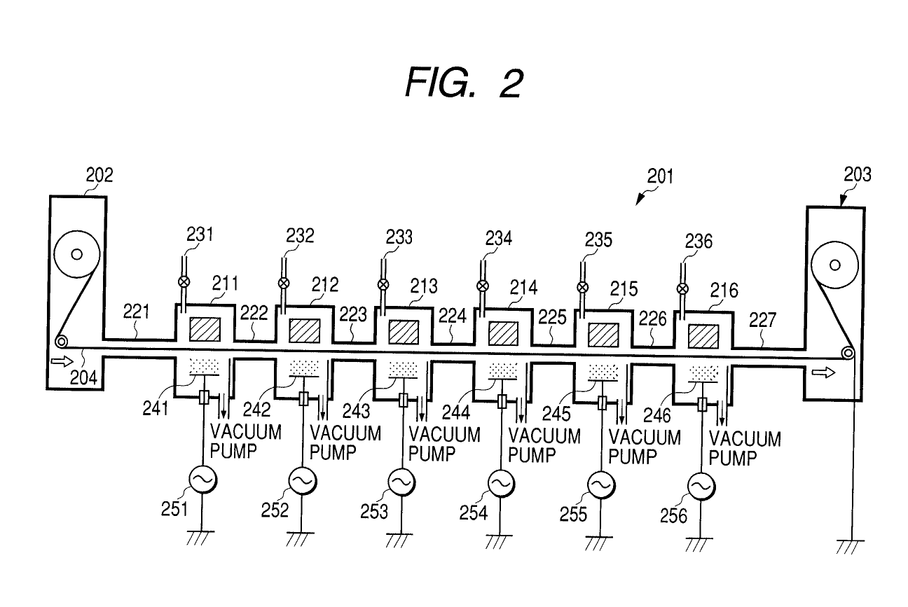

Using a deposited-film formation apparatus 201 shown in FIG. 2, silicon-type thin films were formed according to the following procedure.

FIG. 2 is a diagrammatic cross-sectional view showing an example of a deposited-film formation apparatus for producing silicon-type thin films and photovoltaic devices according the present invention. The deposited-film formation apparatus 201 shown in FIG. 2 is basically constituted of a substrate wind-off container 202, semiconductor-forming vacuum containers 211 to 216 and a substrate wind-up container 203 which are connected via gas gates 221 to 227. In this deposited-film formation apparatus 201, a beltlike conductive substrate 204 is so set as to pass through each container and each gas gate. The beltlike conductive substrate 204 is wound off from a bobbin set in the substrate wind-off container 202 and is wound up on another bobbin in the substrate wind-up container 203.

The semiconductor-forming vacuum containers 211 to 216 each have a deposition chamber. To high-frequency power guides 241 to 246 in the respective deposition chambers, high-frequency power is applied from high-frequency power sources 251 to 256 to cause glow discharge to take place, by which material gases are decomposed to form a semiconductor layer on the beltlike conductive substrate 204. Gas feed lines 231 to 236 through which material gases and dilute gas are fed are also connected to the semiconductor-forming vacuum containers 211 to 216.

The deposited-film formation apparatus 201 shown in FIG. 2 has six semiconductor-forming vacuum containers. In the following Examples, it may be unnecessary to cause the glow discharge to take place in all the semiconductor-forming vacuum containers. Whether or not the glow discharge be taken place may be selected for each container in accordance with the layer construction of the photovoltaic device to be produced. Also, in each semiconductor-forming vacuum container, a film-forming region regulation plate (not shown) is provided which is to regulate the area of contact of the beltlike conductive substrate 204 with discharge space in each deposition chamber so that the layer thickness of each semiconductor layer formed in each container can be regulated by regulating this plate.

First, a beltlike substrate (40 cm wide, 200 m long and 0.125 mm thick) made of stainless steel (SUS430BA) was thoroughly degreased and cleaned, and was set in a continuous sputtering apparatus (not shown) to deposit a 100 nm thick Ag thin film by sputtering using an Ag electrode as a target. Using a ZnO target, a 1.2 μm thick ZnO thin film was further deposited on the Ag thin film by sputtering to form the beltlike conductive substrate 204.

Next, a bobbin around which the beltlike conductive substrate 204 had been wound was set in the substrate wind-off container 202. Then the beltlike conductive substrate 204 was passed through the bring-in side gas gate, semiconductor-forming vacuum containers 211, 212, 213, 214, 215 and 216 and bring-out side gas gate, up to the substrate wind-up container 203, and its tension was regulated so that the beltlike conductive substrate 204 did not sag. Next, the insides of the substrate wind-off container 202, semiconductor-forming vacuum containers 211, 212, 213, 214, 215 and 216 and substrate wind-up container 203 were sufficiently evacuated to a vacuum of 5×10⁻⁶ Torr or below by means of an evacuation system (not shown) having a vacuum pump.

Next, operating the evacuation system, material gases and dilute gas were fed into the semiconductor-forming vacuum container 212 through the gas feed line 232.

To the semiconductor-forming vacuum containers other than the semiconductor-forming vacuum container 212, 200 00 sccm of H₂ gas was also fed through the corresponding gas feed lines. Simultaneously, to the respective gas gates, 500 sccm of H₂ gas was fed through corresponding gate gas feed lines (not shown). In this state, evacuation capacity of the evacuation system was regulated to bring the pressure inside the semiconductor-forming vacuum container 212 to a desired pressure. Conditions for film deposition are as shown in Table 1.

TABLE 1
Material gases (Example 1-1):

| | |
|---|---|
| SiF₄ (with 0.1 ppm of oxygen): | 50 sccm |
| H₂: | 300 sccm |
| Substrate temperature: | 400° C. |
| Pressure: | 100 mTorr |

At the time the pressure in the semiconductor-forming vacuum container 212 became stable, the beltlike conductive substrate 204 was began to move from the substrate wind-off container 202 toward the substrate wind-up container 203.

Next, high-frequency power was applied from the high-frequency power source 252 to the high-frequency power guide 242 inside the semiconductor-forming vacuum container 212 to cause glow discharge to take place in the deposition chamber inside the semiconductor-forming vacuum container 212, thus a silicon-type thin film was formed on the beltlike conductive substrate 204 in a thickness of 1 μm (Example 1-1). Here, high-frequency power having a frequency of 2.45 GHz and a power of 300 W was guided into the semiconductor-forming vacuum container 212 from the high-frequency power guide 242.

Next, changing the material gases as shown in Table 2, silicon-type thin films were formed in the same manner as in Example 1-1 (Examples 1-2 and 1-3 and Comparative Examples 1-1 and 1-2).

Diffraction peaks of the silicon-type thin films prepared in Examples 1-1 to 1-3 and Comparative Examples 1-1 and 1-2 were measured with an X-ray diffraction apparatus to examine the proportion of the (220)-plane diffraction intensity to the total diffraction intensity, and also Scherrer radius was determined from the half width of a diffraction peak of the (220)-reflection. Urbach energy was also measured by the constant photocurrent method (CPM), and the oxygen content in the silicon-type thin film by SIMS (secondary ion mass spectroscopy). Results obtained on these are shown in Table 3.

As shown in Table 3, the silicon-type thin films of Examples 1-1 to 1-3 have better (220)-plane orientation preference and crystal grain diameter than those of the silicon-type thin films of Comparative Examples 1-1 and 1-2, and also have film quality superior to that of the latter. As can be seen from the foregoing, the silicon-type thin film of the present invention has superior characteristics.

TABLE 2
Material gases (Example 1-2):

| | |
|---|---|
| SiF₄ (with 0.3 ppm of oxygen): | 50 sccm |
| H₂: | 300 sccm |

Material gases (Example 1-3):

| | |
|---|---|
| SiF₄ (with 0.5 ppm of oxygen): | 50 sccm |
| H₂: | 300 sccm |

Material gases (Comparative Example 1-1):

| | |
|---|---|
| SiF₄ (with 0.05 ppm of oxygen): | 50 sccm |
| H₂: | 300 sccm |

Material gases (Comparative Example 1-2):

| | |
|---|---|
| SiF₄ (with 1.0 ppm of oxygen): | 50 sccm |
| H₂: | 300 sccm |

TABLE 3

| | | | |
|---|---|---|---|
| Proportion of | | | |
| (220)-plane | | | |
| diffraction | | | |
| intensity to | | | Oxygen |
| total film | Scherrer | | concentration |
| diffraction | radius of | Urbach | in thin film |
| intensity | (220)-plane | energy | (atoms/cm³) |

Example 1-1:

| | | | |
|---|---|---|---|
| 1 | 1 | 40 meV | 1.5 × 10¹⁸ |

Example 1-2:

| | | | |
|---|---|---|---|
| 1.02 | 1.05 | 45 meV | 7.0 × 10¹⁷ |

Example 1-3:

| | | | |
|---|---|---|---|
| 1.02 | 1.0 | 40 meV | 5.0 × 10¹⁹ |

Comparative Example 1-1:

| | | | |
|---|---|---|---|
| 0.9 | 1.0 | 60 meV | 1.0 × 10¹⁸ |

Comparative Example 1-2:

| | | | |
|---|---|---|---|
| 0.9 | 0.85 | 60 meV | 1.0 × 10²⁰ |

“Proportion of (220)-plane diffraction intensity to total diffraction intensity” and “Scherrer radius of (220)-plane” are the values found by standardizing the value of Example 1-1 as 1.

### Example 2

Using the deposited-film formation apparatus 201 shown in FIG. 2, silicon-type thin films were formed according to the following procedure.

In the same manner as in Example 1, the beltlike conductive substrate 204 was prepared and was set in the deposited-film formation apparatus 201. Then the insides of the substrate wind-off container 202, semiconductor-forming vacuum containers 211, 212, 213, 214, 215 and 216 and substrate wind-up container 203 were sufficiently evacuated to a vacuum of 5×10⁻⁶ Torr or below by means of an evacuation system (not shown) having a vacuum pump.

Next, operating the evacuation system, material gases and dilute gas were fed into the semiconductor-forming vacuum container 212 through the gas feed line 232.

To the semiconductor-forming vacuum containers other than the semiconductor-forming vacuum container 212, 200 sccm of H₂ gas was also fed through the corresponding gas feed lines. Simultaneously, to the respective gas gates, 500 sccm of H₂ gas was fed through corresponding gate gas feed lines (not shown). In this state, evacuation capacity of the evacuation system was regulated to bring the pressure inside the semiconductor-forming vacuum container 212 to a desired pressure.

Next, high-frequency power was applied from the high-frequency power source 252 to the high-frequency power guide 242 inside the semiconductor-forming vacuum container 212 to cause glow discharge to take place in the deposition chamber inside the semiconductor-forming vacuum container 212, to form on the beltlike conductive substrate 204 an i-type semiconductor layer (layer thickness: 1 μm) containing crystalline phase, thus a silicon-type thin film was formed. Here, high-frequency power having a frequency of 2.45 GHz and a power of 300 W was guided into the semiconductor-forming vacuum container 212 from the high-frequency power guide 242. Also, the silicon-type thin films were formed changing H₂ flow rate as shown in Table 4 (Examples 2-1, 2-2 and 2-3).

TABLE 4
Film-forming conditions in 212

| | |
|---|---|
| Material gases: | |
| SiF₄ (with 0.3 ppm of oxygen): | 50 sccm |
| H₂: | 25 sccm (Example 2-1) |
| H₂: | 50 sccm (Example 2-2) |
| H₂: | 75 sccm (Example 2-3) |
| Substrate temperature: | 400° C. |
| Pressure: | 100 mTorr |

Raman scattering spectra of the silicon-type thin films prepared in Examples 2-1 to 2-3 were measured to examine the ratio of Raman scattering intensity at around 520 cm⁻¹ (due to crystalline component) to that at around 480 cm⁻¹ (due to amorphous component). Urbach energy was also measured by the constant photocurrent method (CPM). Results obtained on these are shown in Table 5.

TABLE 5

| | Example 2-1 | Example 2-2 | Example 2-3 |
|---|---|---|---|
| SiF₄/H₂: | 50/25 | 50/50 | 50/75 |
| Raman scattering | | | |
| intensity ratio: | | | |
| (520 cm⁻¹/480 cm⁻¹) | 5.0 | 8.0 | 8.3 |
| Urbach energy: | 45 meV | 40 meV | 40 meV |

As can be seen therefrom, the silicon-type thin films of Examples 2-1 to 2-3 show superior crystallizability and also have superior film quality, and have much superior characteristics when SiF₄<H₂.

### Example 3

Using the deposited-film formation apparatus 201 shown in FIG. 2, silicon-type thin films were formed according to the following procedure.

In the same manner as in Example 1, the beltlike conductive substrate 204 was prepared and was set in the deposited-film formation apparatus 201. Then the insides of the substrate wind-off container 202, semiconductor-forming vacuum containers 211, 212, 213, 214, 215 and 216 and substrate wind-up container 203 were sufficiently evacuated to a vacuum of 5×10⁻⁶ Torr or below by means of an evacuation system (not shown) having a vacuum pump.

Next, operating the evacuation system, material gases and dilute gas were fed into the semiconductor-forming vacuum container 212 through the gas feed line 232.

To the semiconductor-forming vacuum containers other than the semiconductor-forming vacuum container 212, 200 00 sccm of H₂ gas was also fed through the corresponding gas feed lines. Simultaneously, to the respective gas gates, 500 sccm of H₂ gas was fed through corresponding gate gas feed lines (not shown).

Next, high-frequency power was applied from the high-frequency power source 252 to the high-frequency power guide 242 inside the semiconductor-forming vacuum container 212 to cause glow discharge to take place in the deposition chamber inside the semiconductor-forming vacuum container 212, to form on the beltlike conductive substrate 204 an i-type semiconductor layer (layer thickness: 1 μm) containing crystalline phase, thus a silicon-type thin film was formed. Here, high-frequency power having a frequency of 2.45 GHz and a power of 500 W was guided into the semiconductor-forming vacuum container 212 from the high-frequency power guide 242. Also, the silicon-type thin films were formed changing the pressure inside the semiconductor-forming vacuum container 212 as shown in Table 6 (Examples 3-1, 3-2 and 3-3).

TABLE 6
Film-forming conditions in 212

| | |
|---|---|
| Material gases: | |
| SiF₄ (with 0.3 ppm of oxygen): | 50 sccm |
| H₂: | 300 sccm |
| Substrate temperature: | 400° C. |
| Pressure: | 40 mTorr (Example 3-1) |
| | 50 mTorr (Example 3-2) |
| | 60 mTorr (Example 3-3) |

Diffraction peaks of the silicon-type thin films prepared in Examples 3-1 to 3-3 were measured with an X-ray diffraction apparatus to examine the proportion of the (220)-plane diffraction intensity to the total diffraction intensity, and also Scherrer radius was determined from the half width of a diffraction peak of the (220)-reflection. Urbach energy was also measured by the constant photocurrent method (CPM). Results obtained on these are in Table 7.

TABLE 7

| | Example 3-1 | Example 3-2 | Example 3-3 |
|---|---|---|---|
| Pressure: | 30 mTorr | 50 mTorr | 70 mTorr |
| Proportion of (220)-plane | 1 | 1.05 | 1.08 |
| diffraction intensity to | | | |
| total diffraction intensity: | | | |
| Scherrer radius of | 1 | 1.07 | 1.08 |
| (220)-plane: | | | |
| Urbach energy: | 50 meV | 41 meV | 42 meV |

“Proportion of (220)-plane diffraction intensity to total diffraction intensity” and “Scherrer radius of (220)-plane” are the values found by standardizing the value of Example 3-1 as 1.

As shown in Table 7, the silicon-type thin films of Examples 3-1 to 3-3 have strong (220)-plane orientation preference, large crystal grain diameter and good film quality. As can be seen from the foregoing, the silicon-type thin film of the present invention has superior characteristics. Especially when the pressure PR inside the semiconductor-forming vacuum container 212 is 50 mTorr or higher, it has much superior characteristics.

### Example 4

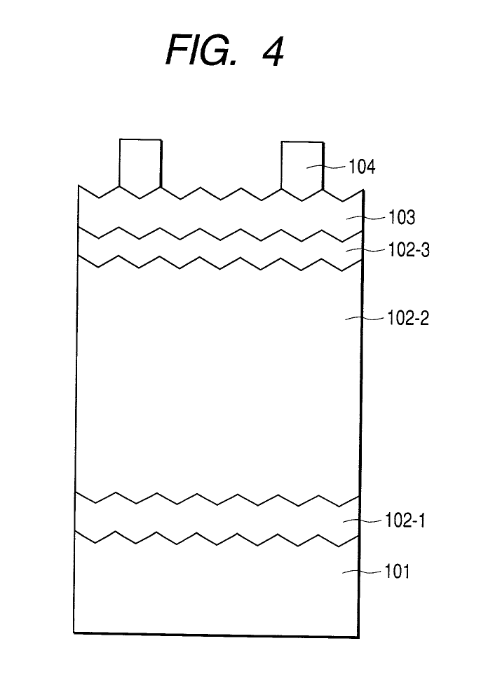

Using the deposited-film formation apparatus 201 shown in FIG. 2, a p-i-n type photovoltaic device shown in FIG. 4 was produced according to the following procedure. FIG. 4 is a diagrammatic cross-sectional view showing an example of a photovoltaic device having the silicon-type thin film of the present invention. In FIG. 4, the same members as those in FIG. 1 are denoted by like reference numerals to omit repeating the description. The semiconductor layer of this photovoltaic device consists of an amorphous n-type semiconductor layer 102-1, an i-type semiconductor layer 102-2 containing crystalline phase and a microcrystalline p-type semiconductor layer 102-3. That is, this photovoltaic device is what is called a p-i-n type single-cell photovoltaic device.

In the same manner as in Example 1, the beltlike conductive substrate 204 was prepared and was set in the deposited-film formation apparatus 201. Then the insides of the substrate wind-off container 202, semiconductor-forming vacuum containers 211, 212, 213, 214, 215 and 216 and substrate wind-up container 203 were sufficiently evacuated to a vacuum of 5×10⁻⁶ Torr or below by means of an evacuation system (not shown) having a vacuum pump.

Next, operating the evacuation system, material gases and dilute gases were fed into the semiconductor-forming vacuum containers 211 to 213 through the gas feed lines 231 to 233, respectively.

To the semiconductor-forming vacuum containers other than the semiconductor-forming vacuum containers 211 to 213, 200 sccm of H₂ gas was also fed through the corresponding gas feed lines. Simultaneously, to the respective gas gates, 500 sccm of H₂ gas was fed through corresponding gate gas feed lines (not shown). In this state, evacuation capacity of the evacuation system was regulated to bring the pressure inside the semiconductor-forming vacuum containers 211 to 213 each to a desired pressure. Conditions for film deposition are as shown in Table 8.

TABLE 8
Film-forming conditions in 211

| | |
|---|---|
| Material gases: | |
| SiH₄: | 20 sccm |
| H₂: | 100 sccm |
| PH₃ (diluted to 2% with H₂ ): | 30 sccm |
| Substrate temperature: | 300° C. |
| Pressure: | 1.0 Torr |

Film-forming conditions in 212

| | |
|---|---|
| Material gases: | |
| SiF₄ (with 0.3 ppm of oxygen): | 50 sccm |
| H₂: | 300 sccm |
| Substrate temperature: | 400° C. |
| Pressure: | 100 mTorr |

Film-forming conditions in 213

| | |
|---|---|
| Material gases: | |
| SiH₄: | 10 sccm |
| H₂: | 800 sccm |
| BF₃ (diluted to 2% with H₂): | 100 sccm |
| Substrate temperature: | 200° C. |
| Pressure: | 1.2 Torr |

At the time the pressure in the semiconductor-forming vacuum containers 211 to 213 became stable, the beltlike conductive substrate 204 was began to move from the substrate wind-off container 202 toward the substrate wind-up container 203.

Next, high-frequency power was applied from the high-frequency power sources 251 to 253 to the high-frequency power guides 241 to 243 inside the semiconductor-forming vacuum containers 211 to 213 to cause glow discharge to take place in the deposition chambers inside the semiconductor-forming vacuum containers 211 to 213, to form on the beltlike conductive substrate 204 an amorphous n-type semiconductor layer (layer thickness: 30 nm), an i-type semiconductor layer containing crystalline phase (layer thickness: 1.5 μm) and a microcrystalline p-type semiconductor layer (layer thickness: 10 nm), thus a photovoltaic device was formed.

Here, high-frequency power having a frequency of 13.56 MHz and a power density of 5 mW/cm³ was guided into the semiconductor-forming vacuum container 211, and high-frequency power having a frequency of 13.56 MHz and a power density of 30 mW/cm³ to the semiconductor-forming vacuum container 213. Also, high-frequency power having a frequency of 2.45 GHz and a power of 300 W was guided into the semiconductor-forming vacuum container 212 from the high-frequency power guide 242.

Then, using a continuous module assembly machine (not shown), the beltlike photovoltaic device thus produced was worked into 36 cm×22 cm solar-cell modules (Example 4).

Next, solar-cell modules were produced in the same manner as in Example 4 except that the material gases fed into the semiconductor-forming vacuum container 212 were changed to SiF₄ (with introduction of 0.05 ppm of oxygen): 50 sccm and H₂: 300 sccm (Comparative Example 4).

Photoelectric conversion efficiency of the solar-cell modules produced in Example 4 and Comparative Example 4 was measured with a solar simulator (AM 1.5; 100 mW/cm²). Standardizing as 1 the photoelectric conversion efficiency of the solar-cell module of Example 4, the value of photoelectric conversion efficiency of the solar-cell module produced in Comparative Example 4 was found to be 0.92.

Adherence between the conductive substrate and the semiconductor layer was also examined by cross-cut taping (cross-cut test; gap width of cuts: 1 mm; number of square cuts: 100). Also, a solar-cell module whose initial photoelectric conversion efficiency was previously measured was placed in a dark place having a temperature of 85° C. and a humidity of 85%RH and kept there for 30 minutes. Thereafter, this solar-cell module was cooled to a temperature of −20° C. over a period of 70 minutes and kept at this temperature for 30 minutes, which was then again returned to the temperature of 85° C. and humidity of 85%RH over a period of 70 minutes. This cycle was repeated 100 times, and thereafter its photoelectric conversion efficiency was again measured to examine any changes in photoelectric conversion efficiency which were caused by such a temperature and humidity test. Also, a solar-cell module whose initial photoelectric conversion efficiency was previously measured was kept at 50° C. and in this state exposed to artificial sunlight of AM 1.5 and 100 mW/cm² for 500 hours. Thereafter, its photoelectric conversion efficiency was again measured to examine any changes in photoelectric conversion efficiency which were caused by such a photodeterioration test. Results obtained on these are shown in Table 9.

TABLE 9

| | | Comparative |
|---|---|---|
| | Example 4 | Example 4 |
| Initial photoelectric conversion | 1 | 0.92 |
| efficiency: | | |
| Number of square cuts remaining | 1 | 0.95 |
| after cross-cut taping: | | |
| Changes in photoelectric conversion | 1.0 | 0.93 |
| efficiency caused by temperature and | | |
| humidity test (efficiency after test/ | | |
| initial efficiency): | | |
| Changes in photoelectric conversion | 1.0 | 0.93 |
| efficiency caused by | | |
| photodeterioration test: | | |

“Initial photoelectric conversion efficiency” and “Number of square cuts remaining after cross-cut taping” are the values found by standardizing the value of Example 4 as 1.

As can be seen from the foregoing, the solar-cell module having the photovoltaic device of the present invention has superior characteristic features.

### Example 5

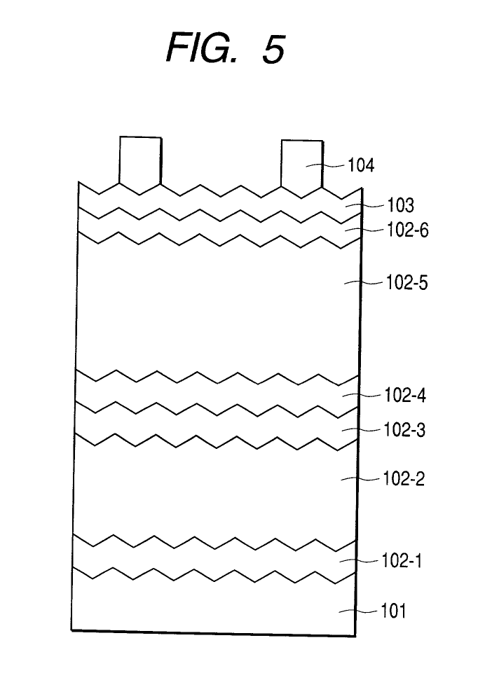

Using the deposited-film formation apparatus 201 shown in FIG. 2, a photovoltaic device shown in FIG. 5 was produced according to the following procedure. FIG. 5 is a diagrammatic cross-sectional view showing an example of a photovoltaic device having the silicon-type thin film of the present invention. In FIG. 5, the same members as those in FIG. 1 are denoted by like reference numerals to omit repeating the description. The semiconductor layer of this photovoltaic device consists of an amorphous n-type semiconductor layer 102-1, an i-type semiconductor layer 102-2 containing crystalline phase, a microcrystalline p-type semiconductor layer 102-3, an amorphous n-type semiconductor layer 102-4, a microcrystalline i-type semiconductor layer 102-5 and a microcrystalline p-type semiconductor layer 102-6. That is, this photovoltaic device is what is called a p-i-n p-i-n type double-cell photovoltaic device.

In the same manner as in Example 1, the beltlike conductive substrate 204 was prepared and was set in the deposited-film formation apparatus 201. Then the insides of the substrate wind-off container 202, semiconductor-forming vacuum containers 211, 212, 213, 214, 215 and 216 and substrate wind-up container 203 were sufficiently evacuated to a vacuum of 5×10⁻⁶ Torr or below by means of an evacuation system (not shown) having a vacuum pump.

Next, operating the evacuation system, material gases and dilute gases were fed into the semiconductor-forming vacuum containers 211 to 216 through the gas feed lines 231 to 236, respectively.

To the respective gas gates, 500 sccm of H₂ gas was also fed through corresponding gate gas feed lines (not shown). In this state, evacuation capacity of the evacuation system was regulated to bring the pressure inside the semiconductor-forming vacuum containers 211 to 216 each to a desired pressure. Films were formed under conditions as shown in Table 8, for both the bottom cell and the top cell.

At the time the pressure in the semiconductor-forming vacuum containers 211 to 216 became stable, the beltlike conductive substrate 204 was began to move from the substrate wind-off container 202 toward the substrate wind-up container 203.

Next, high-frequency power was applied from the high-frequency power sources 251 to 256 to the high-frequency power guides 241 to 246 inside the semiconductor-forming vacuum containers 211 to 216 to cause glow discharge to take place in the deposition chambers inside the semiconductor-forming vacuum containers 211 to 216, to form on the beltlike conductive substrate 204 an amorphous n-type semiconductor layer (layer thickness: 30 nm), an i-type semiconductor layer containing crystalline phase (layer thickness: 2.0 μm) and a microcrystalline p-type semiconductor layer (layer thickness: 10 nm), thus a bottom cell was prepared. Further thereon an amorphous n-type semiconductor layer (layer thickness: 30 nm), an i-type semiconductor layer containing crystalline phase (layer thickness: 1.2 μm) and a microcrystalline p-type semiconductor layer (layer thickness: 10 nm) were formed to prepare a top cell. Thus, a double-cell photovoltaic device was produced.

Here, high-frequency power having a frequency of 13.56 MHz and a power density of 5 mW/cm³ was guided into the semiconductor-forming vacuum containers 211 and 214, and high-frequency power having a frequency of 13.56 MHz and a power density of 30 mW/cm³ to the semiconductor-forming vacuum containers 213 and 216. Also, high-frequency power having a frequency of 2.45 GHz and a power of 300 W was guided into the semiconductor-forming vacuum containers 212 and 215 from the high-frequency power guides 242 and 245, respectively.

Then, using a continuous module assembly machine (not shown), the beltlike photovoltaic device thus produced was worked into 36 cm×22 cm solar-cell modules (Example 5).

The solar-cell module of Example 5 showed a photoelectric conversion efficiency 1.2 times that of the solar-cell module of Example 4. Also, the solar-cell module of Example 5 showed superior durability to the temperature and humidity test. As can be seen from these, the solar-cell module having the photovoltaic device of the present invention has superior characteristic features.

As described above, in the process for forming the silicon-type thin film by high-frequency plasma CVD, silicon fluoride and hydrogen are contained in a material gas and oxygen atoms are incorporated in the material gas in a concentration of from 0.1 ppm to 0.5 ppm based on that of silicon atoms. Thus, silicon-type thin films having a high crystallinity and a good crystallizability and oriented in the (220)-direction can be deposited at a high rate. The present silicon-type thin film is used in at least part of at least one i-type semiconductor layer of the photovoltaic device comprising the substrate and formed thereon the semiconductor layer having at least one set of p-i-n junction. Thus, photovoltaic devices having a good photoelectric conversion efficiency and superior adherence and environmental resistance can be formed at a cost made greatly lower than ever.

What is claimed is:

1. A process for forming a silicon-type thin film by high-frequency plasma chemical vapor deposition, wherein silicon fluoride and hydrogen are contained in a material gas and oxygen atoms are incorporated in the material gas in a concentration of from 0.1 ppm to 0.5 ppm based on that of silicon atoms.

2. The process according to claim 1, wherein the hydrogen in the material gas is fed at a flow rate not lower than the flow rate of the silicon fluoride.

3. The process according to claim 1, wherein the silicon-type thin film is formed at a pressure of 50 mTorr or higher.

4. A silicon-type thin film formed by high-frequency plasma chemical vapor deposition, the silicon-type thin film having been formed under conditions that silicon fluoride and hydrogen are contained in a material gas and oxygen atoms are incorporated in the material gas in a concentration of from 0.1 ppm to 0.5 ppm based on that of silicon atoms.

5. The silicon-type thin film according to claim 4, which contains the oxygen atoms in an amount of from 1.5×10¹⁸ atoms/cm³ to 5.0×10¹⁹ atoms/cm³.

6. The silicon-type thin film according to claim 4, wherein the hydrogen in the material gas has been fed at a flow rate not lower than the flow rate of the silicon fluoride.

7. The silicon-type thin film according to claim 4, wherein the silicon-type thin film has been formed at a pressure of 50 mTorr or higher.

8. The silicon-type thin film according to claim 4, wherein the silicon-type thin film has a Raman scattering intensity due to crystalline component which intensity is at least three times the Raman scattering intensity due to amorphous component.

9. The silicon-type thin film according to claim 4, wherein the silicon-type thin film has a diffraction intensity of the (220)-plane as measured by X-ray or electron-ray diffraction, which is in a proportion of 50% or more with respect to the total diffraction intensity.

10. A photovoltaic device comprising a substrate and formed thereon a semiconductor layer having at least one set of p-i-n junction, wherein at least one i-type semiconductor layer has been formed by a process for forming a silicon-type thin film by high-frequency plasma chemical vapor deposition, the i-type semiconductor layer having been formed under conditions that silicon fluoride and hydrogen are contained in a material gas and oxygen atoms are incorporated in the material gas in a concentration of from 0.1 ppm to 0.5 ppm based on that of silicon atoms.

11. The photovoltaic device according to claim 10, wherein the i-type semiconductor layer contains the oxygen atoms in an amount of from 1.5×10¹⁸ atoms/cm³ to 5.0×10¹⁹ atoms/cm³.

12. The photovoltaic device according to claim 10, wherein the hydrogen in the material gas has been fed at a flow rate not lower than the flow rate of the silicon fluoride.

13. The photovoltaic device according to claim 10, wherein the i-type semiconductor layer has been formed at a pressure of 50 mTorr or higher.

14. The photovoltaic device according to claim 10, wherein the i-type semiconductor layer has a Raman scattering intensity due to crystalline component which intensity is at least three times the Raman scattering intensity due to amorphous component.

15. The photovoltaic device according to claim 10, wherein the i-type semiconductor layer has a diffraction intensity of the (220)-plane as measured by X-ray or electron-ray diffraction, which is in a proportion of 50% or more with respect to the total diffraction intensity.

16. A silicon-type thin film containing oxygen atoms in an amount of from 1.5×10¹⁸ atoms/cm³ to 5.0×10¹⁹ atoms/cm³.

17. The silicon-type thin film according to claim 16, which has a Raman scattering intensity due to crystalline component which intensity is at least three times the Raman scattering intensity due to amorphous component.

18. The silicon-type thin film according to claim 16, which has a diffraction intensity of the (220)-plane as measured by X-ray or electron-ray diffraction, which is in a proportion of 50% or more with respect to the total diffraction intensity.

19. A photovoltaic device comprising a substrate and formed thereon a semiconductor layer having at least one set of p-i-n junction, wherein at least one i-type semiconductor layer contains oxygen atoms in an amount of from 1.5×1018 atoms/cm³ to 5.0×1019 atoms/cm³.

20. The photovoltaic device according to claim 19, wherein the i-type semiconductor layer has a Raman scattering intensity due to crystalline component which intensity is at least three times the Raman scattering intensity due to amorphous component.

21. The photovoltaic device according to claim 19, wherein the i-type semiconductor layer has a diffraction intensity of the (220)-plane as measured by X-ray or electron-ray diffraction, which is in a proportion of 50% or more with respect to the total diffraction intensity.
